(19) United States
(12) Patent Application Publication
(10) Pub. No.: US 2018/0088458 A1
(43) Pub. Date: Mar. 29, 2018

(54) COLOR FILTER SUBSTRATE MANUFACTURING METHOD AND COLOR FILTER SUBSTRATE MANUFACTURED WITH SAME

(71) Applicant: Wuhan China Star Optoelectronics Teshnology Co., Ltd., Wuhan City (CN)

(72) Inventor: Jiawun Shen, Wuhan City (CN)

(21) Appl. No.: 15/031,747

(22) PCT Filed: Apr. 14, 2016
(86) PCT No.: PCT/CN2016/079234

§ 371 Date: Apr. 24, 2016

(30) Foreign Application Priority Data
Mar. 7, 2016 (CN) 201610128001.3

(51) Int. Cl. G03F 1/60; G02B 5/20; G03F 7/095; G03F 1/76; G03F 7/00

(52) U.S. Cl. CPC G03F 1/60; G02B 5/201; G02F 1/133516; G03F 1/76; G03F 7/0007; G03F 7/095

(57) ABSTRACT

The present invention provides a CF substrate manufacturing method and a CF substrate manufactured with the method. Through sequentially forming first, second, and third photoresist layers on the base plate and individually subjecting the first, second, and third photoresist layers to patterning, first, second, and third photoresist matrices that are stacked on each other, a plurality of first photoresist blocks, a plurality of second photoresist blocks, and a plurality of third photoresist blocks are formed such that the first, second, and third photoresist matrices have colors that are mixed to exhibit a color of black to thereby serve as a black matrix and the plurality of first photoresist blocks, the plurality of second photoresist blocks, and the plurality of third photoresist blocks are separated from each other by the black matrix and collectively form a color resist layer. The present invention features simultaneously forming a black matrix in manufacturing a color resist layer and, compared to the prior art, saves the time for separately manufacturing the black matrix, saves the material for the black matrix, and reduces the manufacturing cost. The CF substrate of the present invention has a simple structure, a low manufacturing cost, and excellent effect of filtration of light.

### BACKGROUND OF THE INVENTION

### 1. Field of the Invention

The present invention relates to the field of display technology, and in particular to a color filter substrate manufacturing method and a color filter substrate manufactured with the method.

### 2. The Related Arts

With the progress of the display technology, liquid crystal displays (LCDs), due to a variety of advantages, such as high image quality, low power consumption, thin device body, and wide application, have been widely used in various consumer electronic products, such as mobile phones, televisions, personal digital assistants (PDAs), digital cameras, notebook computers, and desktop computers, making them the main stream of display devices.

Most of the liquid crystal display devices that are currently available in the market are backlighting LCDs, which comprise a liquid crystal display panel and a backlight module. The working principle of the liquid crystal display panel is that liquid crystal molecules are arranged between two parallel glass substrates with a number of vertical and horizontal tiny electrical wires arranged between the two glass substrates and the liquid crystal molecules are controlled to rotate according to whether electricity is applied or not so as to refract out light from the backlight module to generate an image.

A liquid crystal display panel is generally composed of a color filter (CF) substrate, a thin-film transistor (TFT) substrate, liquid crystal (LC) interposed between the CF substrate and the TFT substrate, and sealant.

FIG. 1 is a schematic view illustrating a color model adopted in a conventional CF substrate and the color model is referred to as red, green, and blue color model, also referred to as RBG color model. This is a color addition model, where the three primary colors of red, green, and blue are added at different ratios to generate multiple colors of light. FIG. 2 is a schematic cross-sectional view of a conventional CF substrate and FIG. 3 is a top plan view of the CF substrate of FIG. 2. As shown in FIGS. 2 and 3, the CF substrate comprises a backing substrate 100 and a black matrix 200 and a color resist layer 300 formed on the backing substrate 100. The color resist layer 300 comprises a plurality of red resist blocks 310, a plurality of green resist blocks 320, and a plurality of blue resist blocks 330 separated from each other by the black matrix 200. A method for manufacturing the CF substrate generally comprises the following steps: step 1: providing a backing substrate 100, coating a black resist material on the backing substrate 100 to form a black light-shielding layer, and then subjecting the black light-shielding layer to a patterning operation to form a black matrix 200; step 2: sequentially coating a red resist layer, a green resist layer, and a blue resist layer on the backing substrate 100 and subjecting them individually to a patterning operation to form a plurality red resist blocks 310, a plurality of green resist blocks 320, and a plurality of blue resist layers 330 to thereby obtain a color resist layer 300; and then sequentially forming a common electrode and spacers on the color resist layer 300 and the black matrix 200. In the manufacturing method, the black matrix 200, the red resist blocks 310, the green resist blocks 320, the blue resist blocks 330, the common electrode, and the spacers each require an individual process for completion. In other words, totally six processes are needed for completing the manufacturing of the CF substrate. The entire process is complicated; the manufacturing time is extended; and the manufacturing cost is high.

### SUMMARY OF THE INVENTION

An object of the present invention is to provide a color filter (CF) substrate manufacturing method, which requires no individual process for forming a black matrix, saves the consumption of a black matrix material, and shortens the manufacturing time.

Another object of the present invention is to provide a CF substrate, which has a simple structure, low manufacturing cost, and excellent effect of filtration of light.

To achieve the above objects, the present invention provides a CF substrate manufacturing method, which comprises the following steps:

(1) providing a base plate, arranging a black-matrix location on the base plate, and forming a plurality of first, second, and third photoresist-block locations to correspond to the black-matrix location;

(2) applying a first photoresist layer to form a first photoresist matrix and a plurality of first photoresist blocks on the base plate to respectively correspond to the black-matrix location and the first photoresist-block locations;

(3) applying a second photoresist layer to form a second photoresist matrix and a plurality of second photoresist blocks on the base plate to respectively correspond to the black-matrix location and the second photoresist-block locations; and

(4) applying a third photoresist layer to form a third photoresist matrix and a plurality of third photoresist blocks on the base plate to respectively correspond to the black-matrix location and the third photoresist-block locations;

wherein after steps (2)-(4), the first photoresist matrix, the second photoresist matrix, and the third photoresist matrix that are stacked on the black-matrix location exhibits a color of black as a result of color mixture, thereby forming a black matrix, and the plurality of first photoresist blocks, the plurality of second photoresist blocks, and the plurality of third photoresist blocks that are separated from each other by the black matrix form a color resist layer.

Step (2) comprises a process that comprises: coating the first photoresist layer on the base plate, and using a half-tone mask to subject the first photoresist layer to exposure and development so as to form the first photoresist matrix and the plurality of first photoresist blocks on the base plate to respectively correspond to the black-matrix location and the first photoresist-block locations;

step (3) comprises a process that comprises: coating the second photoresist layer on the base plate, the first photoresist matrix, and the plurality of first photoresist blocks, and using a half-tone mask to subject the second photoresist layer to exposure and development so as to form the second photoresist matrix and the plurality of second photoresist blocks on the base plate to respectively correspond to the black-matrix location and the second photoresist-block locations; and

step (4) comprises a process that comprises: coating the third photoresist layer on the base plate, the second photoresist matrix, the plurality of first photoresist blocks, and the plurality of second photoresist blocks, and using a half-tone mask to subject the third photoresist layer to exposure and development so as to form the third photoresist matrix and the plurality of third photoresist blocks on the base plate to respectively correspond to the black-matrix location and the third photoresist-block locations.

In step (2), the first photoresist matrix has a thickness that is 30-35% of a thickness of the first photoresist layer; and the first photoresist blocks have a thickness that is 100% of the thickness of the first photoresist layer;

in step (3), the second photoresist matrix has a thickness that is 30-35% of a thickness of the second photoresist layer and the second photoresist blocks have a thickness that is 100% of the thickness of the second photoresist layer; and

in step (4), the third photoresist matrix has a thickness that is 30-35% of a thickness of the third photoresist layer and the third photoresist blocks have a thickness that is 100% of the thickness of the third photoresist layer.

The first photoresist matrix, the second photoresist matrix, and the third photoresist matrix have thicknesses that are substantially identical.

The first photoresist, the second photoresist, and the third photoresist are a combination of magenta, cyan, and yellow.

The first photoresist, the second photoresist, and the third photoresist have optical densities that are each between 0-4.

The present invention also provides a CF substrate manufacturing method, which comprises the following steps:

(1) providing a base plate, arranging a black-matrix location on the base plate, and forming a plurality of first, second, and third photoresist-block locations to correspond to the black-matrix location;

(2) applying a first photoresist layer to form a first photoresist matrix and a plurality of first photoresist blocks on the base plate to respectively correspond to the black-matrix location and the first photoresist-block locations;

(3) applying a second photoresist layer to form a second photoresist matrix and a plurality of second photoresist blocks on the base plate to respectively correspond to the black-matrix location and the second photoresist-block locations; and

(4) applying a third photoresist layer to form a third photoresist matrix and a plurality of third photoresist blocks on the base plate to respectively correspond to the black-matrix location and the third photoresist-block locations;

wherein after steps (2)-(4), the first photoresist matrix, the second photoresist matrix, and the third photoresist matrix that are stacked on the black-matrix location exhibits a color of black as a result of color mixture, thereby forming a black matrix, and the plurality of first photoresist blocks, the plurality of second photoresist blocks, and the plurality of third photoresist blocks that are separated from each other by the black matrix form a color resist layer; and

wherein step (2) comprises a process that comprises: coating the first photoresist layer on the base plate, and using a half-tone mask to subject the first photoresist layer to exposure and development so as to form the first photoresist matrix and the plurality of first photoresist blocks on the base plate to respectively correspond to the black-matrix location and the first photoresist-block locations;

step (3) comprises a process that comprises: coating the second photoresist layer on the base plate, the first photoresist matrix, and the plurality of first photoresist blocks, and using a half-tone mask to subject the second photoresist layer to exposure and development so as to form the second photoresist matrix and the plurality of second photoresist blocks on the base plate to respectively correspond to the black-matrix location and the second photoresist-block locations; and

step (4) comprises a process that comprises: coating the third photoresist layer on the base plate, the second photoresist matrix, the plurality of first photoresist blocks, and the plurality of second photoresist blocks, and using a half-tone mask to subject the third photoresist layer to exposure and development so as to form the third photoresist matrix and the plurality of third photoresist blocks on the base plate to respectively correspond to the black-matrix location and the third photoresist-block locations.

The present invention also provides a CF substrate, which comprises: a base plate and a black matrix and a color resist layer formed on the base plate, the black matrix comprising a first photoresist matrix, a second photoresist matrix, and a third photoresist matrix stacked on each other such that colors of the first photoresist matrix, the second photoresist matrix, and the third photoresist matrix are mixed to exhibit a color of black, the color resist layer comprising a plurality of first photoresist blocks, a plurality of second photoresist blocks, and a plurality of third photoresist blocks that are separated from each other by the black matrix.

The first photoresist, the second photoresist, and the third photoresist are a combination of magenta, cyan, and yellow.

The first photoresist, the second photoresist, and the third photoresist have optical densities that are each between 0-4.

The first photoresist matrix, the second photoresist matrix, and the third photoresist matrix have thicknesses that are substantially identical.

The efficacy of the present invention is that the present invention provides a CF substrate manufacturing method, which comprises sequentially forming first, second, and third photoresist layers on a base plate and individually subjecting the first, second, and third photoresist layers to patterning to form first, second, and third photoresist matrices that are stacked on each other, a plurality of first photoresist blocks, a plurality of second photoresist blocks, and a plurality of third photoresist blocks, wherein colors of the first, second, and third photoresist matrices are mixed to exhibit a color of black so as to form a black matrix and the plurality of first photoresist blocks, the plurality of second photoresist blocks, and the plurality of third photoresist blocks that are separated from each other by the black matrix collectively form a color resist layer. The present invention features simultaneously forming a black matrix in manufacturing a color resist layer and, compared to the prior art, saves the time for separately manufacturing the black matrix, saves the material for the black matrix, and reduces the manufacturing cost. The present invention provides a CF substrate, which has a simple structure, a low manufacturing cost, and excellent effect of filtration of light.

For better understanding of the features and technical contents of the present invention, reference will be made to the following detailed description of the present invention and the attached drawings. However, the drawings are provided for the purposes of reference and illustration and are not intended to impose limitations to the present invention.

### BRIEF DESCRIPTION OF THE DRAWINGS

The technical solution, as well as other beneficial advantages, of the present invention will be apparent from the following detailed description of embodiments of the present invention, with reference to the attached drawing. In the drawing:

FIG. 1 is a schematic view illustrating a color model adopted in a conventional color filter (CF) substrate;

FIG. 2 is a schematic cross-sectional view of a conventional CF substrate;

FIG. 3 is a top plan view of the CF substrate of FIG. 2;

FIG. 4 is a schematic view illustrating a color model adopted in the present invention;

FIG. 5 is a schematic view illustrating step 1 of a CF substrate manufacturing method according to the present invention;

FIGS. 6 and 7 are schematic views illustrating step 2 of the CF substrate manufacturing method according to the present invention;

FIGS. 8 and 9 are schematic views illustrating step 3 of the CF substrate manufacturing method according to the present invention;

FIGS. 10 and 11 are schematic views illustrating step 4 of the CF substrate manufacturing method according to the present invention; and

FIG. 12 is a schematic view illustrating arrangement of a black matrix and a color resist layer obtained with steps 2-4 according to the present invention.

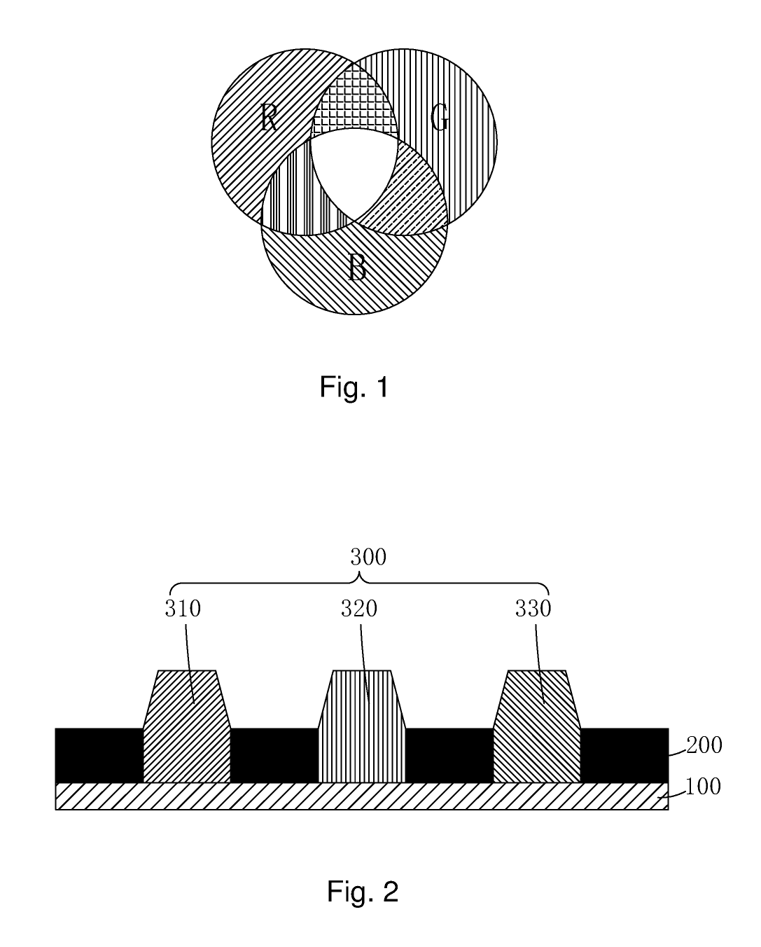

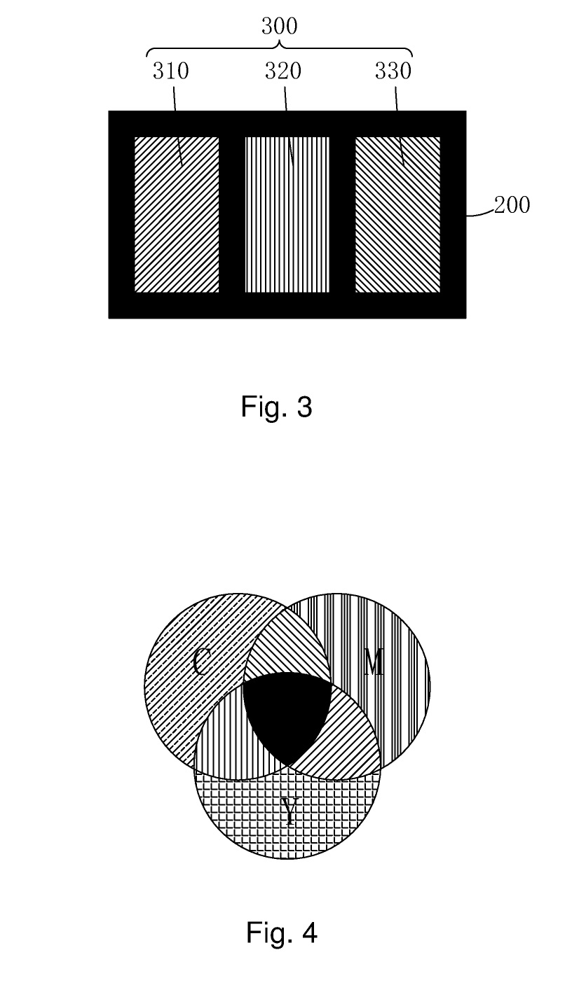

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

The purpose of the present invention is to use the characteristic that gray levels can be produced when multiple color resists are mixed such that in the manufacture of a color resist layer, a plurality of photoresist matrices stacked on each other is formed on a black-matrix location of a base plate and colors, thicknesses, and optical densities (ODs) of the plurality of photoresist matrices are selected and controlled to have a mixture of the colors thereof exhibiting a color of black thereby forming a black matrix. For example, in FIG. 4, a color model that involves magenta (M), cyan (C), and yellow (Y) is adopted to form the color resist layer, and in manufacturing a plurality of magenta, cyan, and yellow photoresist blocks that collectively constitute the color resist layer, photoresist matrices of magenta, cyan, and yellow colors are also formed and stacked on the base plate at a site corresponding to the black-matrix location whereby through controlling the colors, the thicknesses, and optical densities of the magenta, cyan, yellow photoresist matrices, the mixture of the colors can exhibit a color of black to serve as a black matrix. Compared to the prior art, the CF substrate manufacturing method saves the manufacturing time for the black matrix, saves the material for the black matrix, and reduces the manufacturing cost.

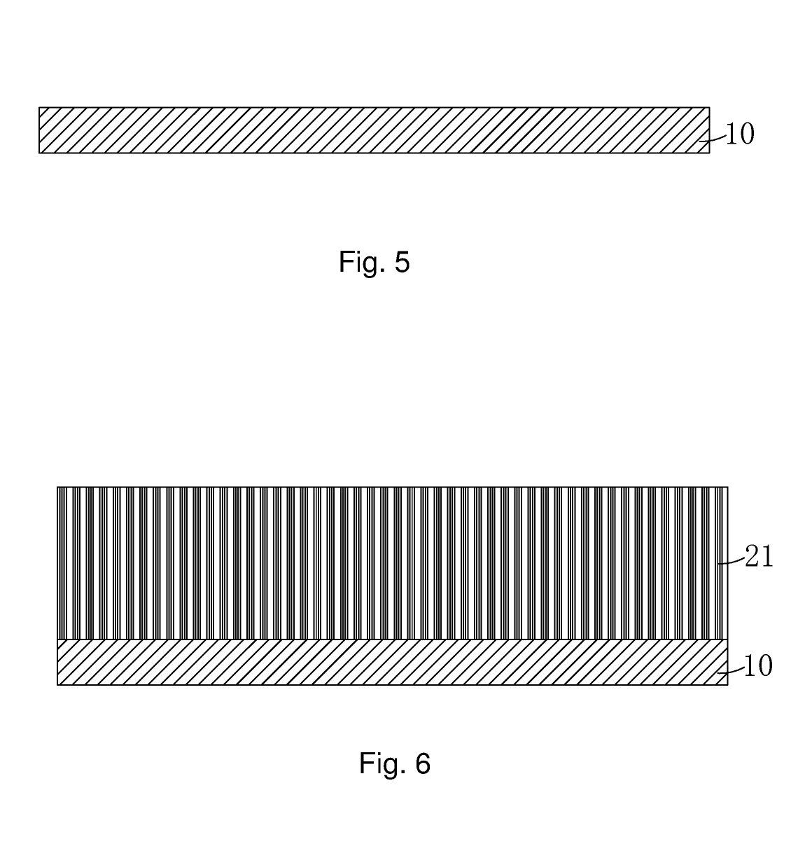

Referring to FIGS. 5-12, the present invention provides a color filter (CF) substrate manufacturing method, which comprises the following steps:

Step 1: as shown in FIG. 5, providing a base plate 10, arranging a black-matrix location on the base plate 10, and forming a plurality of first, second, and third photoresist-block locations to correspond to the black-matrix location.

Specifically, the base plate 10 comprises a transparent plate, preferably a glass plate.

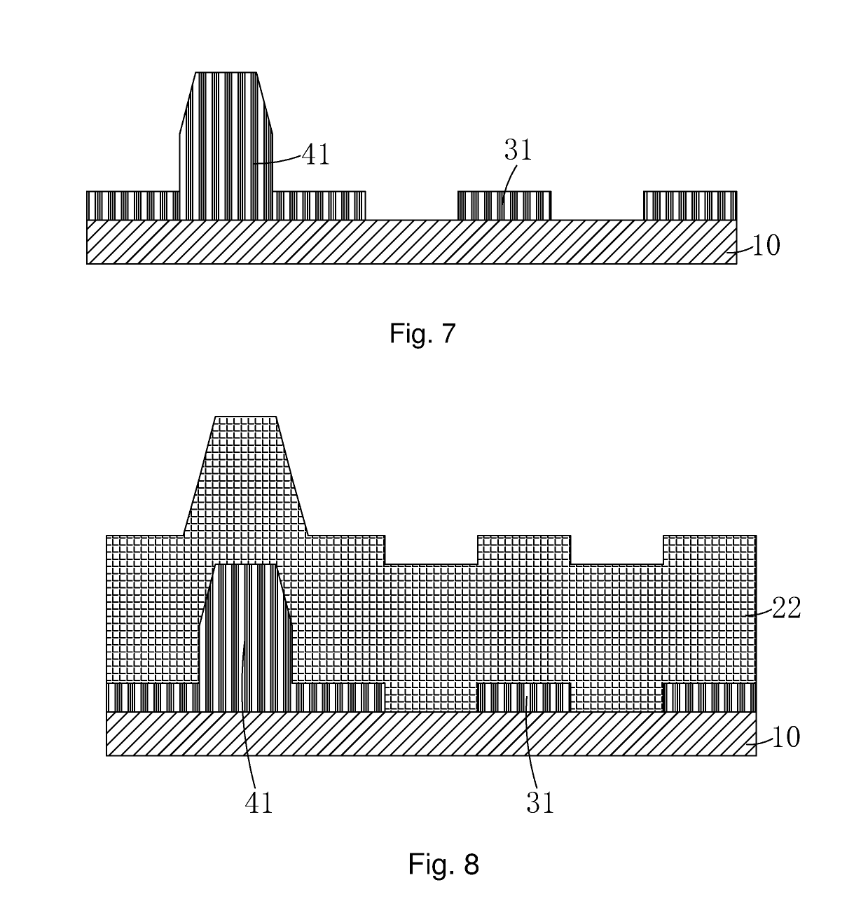

Step 2: as shown in FIGS. 6-7, applying a first photoresist layer 21 to form a first photoresist matrix 31 and a plurality of first photoresist blocks 41 on the base plate 10 to respectively correspond to the black-matrix location and the first photoresist-block locations.

A specific process of Step 2 comprises: coating the first photoresist layer 21 on the base plate 10, and using a half-tone mask to subject the first photoresist layer 21 to exposure and development so as to form the first photoresist matrix 31 and the plurality of first photoresist blocks 41 on the base plate 10 to respectively correspond to the black-matrix location and the first photoresist-block locations.

Specifically, in Step 2, the first photoresist matrix 31 has a thickness that is 30-35% of a thickness of the first photoresist layer 21; and the first photoresist blocks 41 have a thickness that is 100% of the thickness of the first photoresist layer 21.

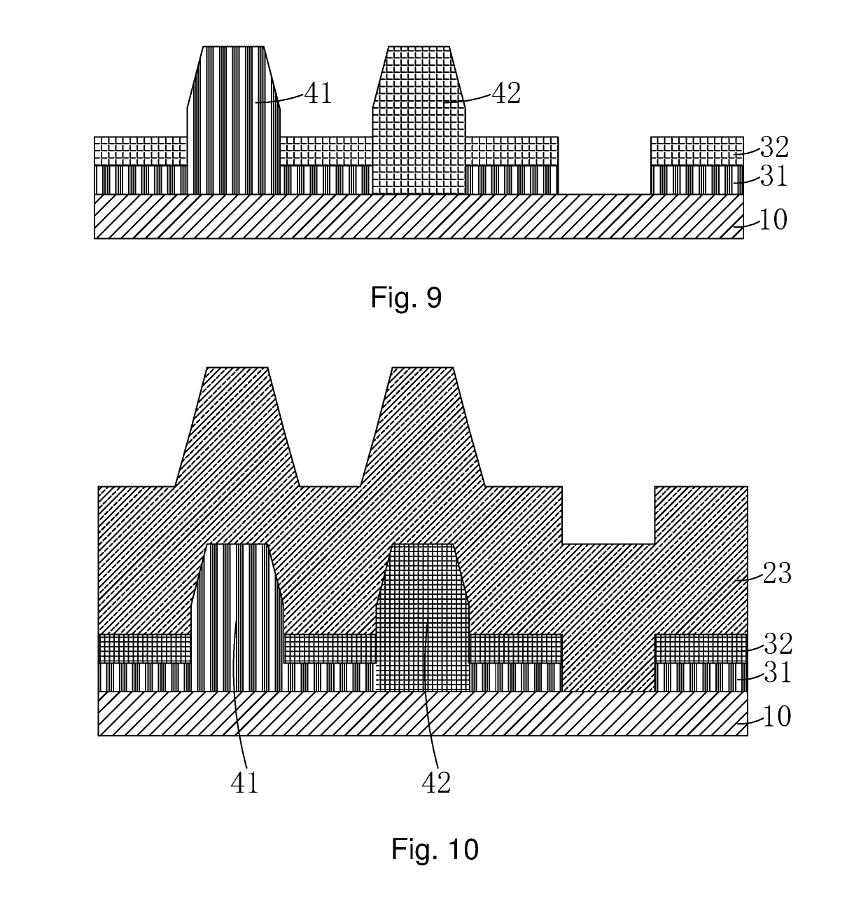

Step 3: as shown in FIGS. 8-9, applying a second photoresist layer 22 to form a second photoresist matrix 32 and a plurality of second photoresist blocks 42 on the base plate 10 to respectively correspond to the black-matrix location and the second photoresist-block locations.

A specific process of Step 3 comprises: coating the second photoresist layer 22 on the base plate 10, the first photoresist matrix 31, and the plurality of first photoresist blocks 41, and using a half-tone mask to subject the second photoresist layer 22 to exposure and development so as to form the second photoresist matrix 32 and the plurality of second photoresist blocks 42 on the base plate 10 to respectively correspond to the black-matrix location and the second photoresist-block locations.

Specifically, in Step 3, the second photoresist matrix 32 has a thickness that is 30-35% of a thickness of the second photoresist layer 22 and the second photoresist blocks 42 have a thickness that is 100% of the thickness of the second photoresist layer 22.

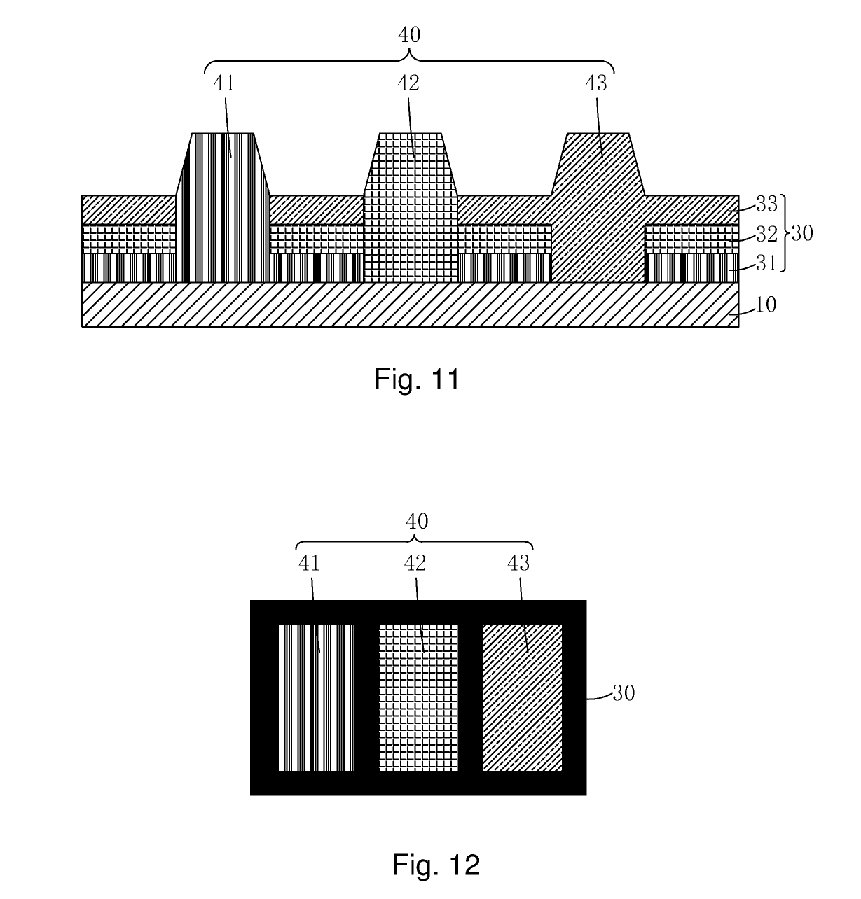

Step 4: as shown in FIGS. 10-11, applying a third photoresist layer 23 to form a third photoresist matrix 33 and a plurality of third photoresist blocks 43 on the base plate 10 to respectively correspond to the black-matrix location and the third photoresist-block locations.

A specific process of Step 4 comprises: coating the third photoresist layer 23 on the base plate 10, the second photoresist matrix 32, the plurality of first photoresist blocks 41, and the plurality of second photoresist blocks 42, and using a half-tone mask to subject the third photoresist layer 23 to exposure and development so as to form the third photoresist matrix 33 and the plurality of third photoresist blocks 43 on the base plate 10 to respectively correspond to the black-matrix location and the third photoresist-block locations.

As shown in FIGS. 11-12, after Step 2-Step 4, the first photoresist matrix 31, the second photoresist matrix 32, and the third photoresist matrix 33 that are stacked on the black-matrix location exhibits a color of black as a result of color mixture, thereby forming a black matrix 30, and the plurality of first photoresist blocks 41, the plurality of second photoresist blocks 42, and the plurality of third photoresist blocks 43 that are separated from each other by the black matrix 30 form a color resist layer 40.

Specifically, in Step 4, the third photoresist matrix 33 has a thickness that is 30-35% of a thickness of the third photoresist layer 23 and the third photoresist blocks 43 have a thickness that is 100% of the thickness of the third photoresist layer 23.

Preferably, the thicknesses of the first photoresist matrix 31, the second photoresist matrix 32, and the third photoresist matrix 33 are substantially identical.

Preferably, the first photoresist, the second photoresist, and the third photoresist are any combination of magenta, cyan, and yellow.

Specifically, the first photoresist, the second photoresist, and the third photoresist each have optical density (OD) between 0-4.

Further, Step 5 is additionally included, wherein a common electrode and spacers are formed, in sequence, on the black matrix 30 and the color resist layer 40.

Specifically, the common electrode is formed of a transparent conductive material, preferably a metal oxide, such as indium tin oxides, indium zinc oxides, aluminum tin oxides, aluminum zinc oxides, and indium germanium zinc oxides.

Specifically, the spacers are formed of a material comprising photoresist.

Referring to FIGS. 11-12, the present invention also provides a CF substrate, which comprises: a base plate 10 and a black matrix 30 and a color resist layer 40 formed on the base plate 10. The black matrix 30 comprises a first photoresist matrix 31, a second photoresist matrix 32, and a third photoresist matrix 33 stacked on each other such that colors of the first photoresist matrix 31, the second photoresist matrix 32, and the third photoresist matrix 33 are mixed to exhibit a color of black. The color resist layer 40 comprises a plurality of first photoresist blocks 41, a plurality of second photoresist blocks 42, and a plurality of third photoresist blocks 43 that are separated from each other by the black matrix 30.

Specifically, the first photoresist, the second photoresist, and the third photoresist are any combination of magenta, cyan, and yellow.

Specifically, the first photoresist, the second photoresist, and the third photoresist each have optical density (OD) between 0-4.

Preferably, the first photoresist matrix 31, the second photoresist matrix 32, and the third photoresist matrix 33 have thicknesses that are substantially identical.

Further, the CF substrate of the present invention also comprises a common electrode and spacers formed on the black matrix 30 and the color resist layer 40.

Specifically, the common electrode is formed of a transparent conductive material, preferably a metal oxide, such as indium tin oxides, indium zinc oxides, aluminum tin oxides, aluminum zinc oxides, and indium germanium zinc oxides.

Specifically, the spacers are formed of a material comprising photoresist.

Specifically, the base plate 10 comprises a transparent plate, preferably a glass plate.

In summary, the present invention provides a CF substrate manufacturing method, which comprises sequentially forming first, second, and third photoresist layers on a base plate and individually subjecting the first, second, and third photoresist layers to patterning to form first, second, and third photoresist matrices that are stacked on each other, a plurality of first photoresist blocks, a plurality of second photoresist blocks, and a plurality of third photoresist blocks, wherein colors of the first, second, and third photoresist matrices are mixed to exhibit a color of black so as to form a black matrix and the plurality of first photoresist blocks, the plurality of second photoresist blocks, and the plurality of third photoresist blocks that are separated from each other by the black matrix collectively form a color resist layer. The present invention features simultaneously forming a black matrix in manufacturing a color resist layer and, compared to the prior art, saves the time for separately manufacturing the black matrix, saves the material for the black matrix, and reduces the manufacturing cost. The present invention provides a CF substrate, which has a simple structure, a low manufacturing cost, and excellent effect of filtration of light.

Based on the description given above, those having ordinary skills of the art may easily contemplate various changes and modifications of the technical solution and technical ideas of the present invention and all these changes and modifications are considered within the protection scope of right for the present invention.

What is claimed is:

1. A color filter (CF) substrate manufacturing method, comprising the following steps:
(1) providing a base plate, arranging a black-matrix location on the base plate, and forming a plurality of first, second, and third photoresist-block locations to correspond to the black-matrix location;
(2) applying a first photoresist layer to form a first photoresist matrix and a plurality of first photoresist blocks on the base plate to respectively correspond to the black-matrix location and the first photoresist-block locations
(3) applying a second photoresist layer to form a second photoresist matrix and a plurality of second photoresist blocks on the base plate to respectively correspond to the black-matrix location and the second photoresist-block locations; and
(4) applying a third photoresist layer to form a third photoresist matrix and a plurality of third photoresist blocks on the base plate to respectively correspond to the black-matrix location and the third photoresist-block locations;
wherein after steps (2)-(4), the first photoresist matrix, the second photoresist matrix, and the third photoresist matrix that are stacked on the black-matrix location exhibits a color of black as a result of color mixture, thereby forming a black matrix, and the plurality of first photoresist blocks, the plurality of second photoresist blocks, and the plurality of third photoresist blocks that are separated from each other by the black matrix form a color resist layer.

2. The CF substrate manufacturing method as claimed in claim 1, wherein step (2) comprises a process that comprises: coating the first photoresist layer on the base plate, and using a half-tone mask to subject the first photoresist layer to exposure and development so as to form the first photoresist matrix and the plurality of first photoresist blocks on the base plate to respectively correspond to the black-matrix location and the first photoresist-block locations;
step (3) comprises a process that comprises: coating the second photoresist layer on the base plate, the first photoresist matrix, and the plurality of first photoresist blocks, and using a half-tone mask to subject the second photoresist layer to exposure and development so as to form the second photoresist matrix and the plurality of second photoresist blocks on the base plate to respectively correspond to the black-matrix location and the second photoresist-block locations; and
step (4) comprises a process that comprises: coating the third photoresist layer on the base plate, the second photoresist matrix, the plurality of first photoresist blocks, and the plurality of second photoresist blocks, and using a half-tone mask to subject the third photoresist layer to exposure and development so as to form the third photoresist matrix and the plurality of third photoresist blocks on the base plate to respectively correspond to the black-matrix location and the third photoresist-block locations.

3. The CF substrate manufacturing method as claimed in claim 1, wherein in step (2), the first photoresist matrix has a thickness that is 30-35% of a thickness of the first photoresist layer; and the first photoresist blocks have a thickness that is 100% of the thickness of the first photoresist layer;
in step (3), the second photoresist matrix has a thickness that is 30-35% of a thickness of the second photoresist layer and the second photoresist blocks have a thickness that is 100% of the thickness of the second photoresist layer; and
in step (4), the third photoresist matrix has a thickness that is 30-35% of a thickness of the third photoresist layer and the third photoresist blocks have a thickness that is 100% of the thickness of the third photoresist layer.

4. The CF substrate manufacturing method as claimed in claim 1, wherein the first photoresist matrix, the second photoresist matrix, and the third photoresist matrix have thicknesses that are substantially identical.

5. The CF substrate manufacturing method as claimed in claim 1, wherein the first photoresist, the second photoresist, and the third photoresist are a combination of magenta, cyan, and yellow.

6. The CF substrate manufacturing method as claimed in claim 1, wherein the first photoresist, the second photoresist, and the third photoresist have optical densities that are each between 0-4.

7. A color filter (CF) substrate manufacturing method, comprising the following steps:
(1) providing a base plate, arranging a black-matrix location on the base plate, and forming a plurality of first, second, and third photoresist-block locations to correspond to the black-matrix location;
(2) applying a first photoresist layer to form a first photoresist matrix and a plurality of first photoresist blocks on the base plate to respectively correspond to the black-matrix location and the first photoresist-block locations;
(3) applying a second photoresist layer to form a second photoresist matrix and a plurality of second photoresist blocks on the base plate to respectively correspond to the black-matrix location and the second photoresist-block locations; and
(4) applying a third photoresist layer to form a third photoresist matrix and a plurality of third photoresist blocks on the base plate to respectively correspond to the black-matrix location and the third photoresist-block locations;
wherein after steps (2)-(4), the first photoresist matrix, the second photoresist matrix, and the third photoresist matrix that are stacked on the black-matrix location exhibits a color of black as a result of color mixture, thereby forming a black matrix, and the plurality of first photoresist blocks, the plurality of second photoresist blocks, and the plurality of third photoresist blocks that are separated from each other by the black matrix form a color resist layer; and
wherein step (2) comprises a process that comprises: coating the first photoresist layer on the base plate, and using a half-tone mask to subject the first photoresist layer to exposure and development so as to form the first photoresist matrix and the plurality of first photoresist blocks on the base plate to respectively correspond to the black-matrix location and the first photoresist-block locations;
step (3) comprises a process that comprises: coating the second photoresist layer on the base plate, the first photoresist matrix, and the plurality of first photoresist blocks, and using a half-tone mask to subject the second photoresist layer to exposure and development so as to form the second photoresist matrix and the plurality of second photoresist blocks on the base plate to respectively correspond to the black-matrix location and the second photoresist-block locations; and
step (4) comprises a process that comprises: coating the third photoresist layer on the base plate, the second photoresist matrix, the plurality of first photoresist blocks, and the plurality of second photoresist blocks, and using a half-tone mask to subject the third photoresist layer to exposure and development so as to form the third photoresist matrix and the plurality of third photoresist blocks on the base plate to respectively correspond to the black-matrix location and the third photoresist-block locations.

8. The CF substrate manufacturing method as claimed in claim 7, wherein in step (2), the first photoresist matrix has a thickness that is 30-35% of a thickness of the first photoresist layer; and the first photoresist blocks have a thickness that is 100% of the thickness of the first photoresist layer;
in step (3), the second photoresist matrix has a thickness that is 30-35% of a thickness of the second photoresist layer and the second photoresist blocks have a thickness that is 100% of the thickness of the second photoresist layer; and
in step (4), the third photoresist matrix has a thickness that is 30-35% of a thickness of the third photoresist layer and the third photoresist blocks have a thickness that is 100% of the thickness of the third photoresist layer.

9. The CF substrate manufacturing method as claimed in claim 7, wherein the first photoresist matrix, the second photoresist matrix, and the third photoresist matrix have thicknesses that are substantially identical.

10. The CF substrate manufacturing method as claimed in claim 7, wherein the first photoresist, the second photoresist, and the third photoresist are a combination of magenta, cyan, and yellow.

11. The CF substrate manufacturing method as claimed in claim 7, wherein the first photoresist, the second photoresist, and the third photoresist have optical densities that are each between 0-4.

12. A color filter (CF) substrate, comprising: a base plate and a black matrix and a color resist layer formed on the base plate, the black matrix comprising a first photoresist matrix, a second photoresist matrix, and a third photoresist matrix stacked on each other such that colors of the first photoresist matrix, the second photoresist matrix, and the third photoresist matrix are mixed to exhibit a color of black, the color resist layer comprising a plurality of first photoresist blocks, a plurality of second photoresist blocks, and a plurality of third photoresist blocks that are separated from each other by the black matrix.

13. The CF substrate as claimed in claim 12, wherein the first photoresist, the second photoresist, and the third photoresist are a combination of magenta, cyan, and yellow.

14. The CF substrate as claimed in claim 12, wherein the first photoresist, the second photoresist, and the third photoresist have optical densities that are each between 0-4.

15. The CF substrate as claimed in claim 12, wherein the first photoresist matrix, the second photoresist matrix, and the third photoresist matrix have thicknesses that are substantially identical.
